(19) United States
(12) Patent Application Publication
(10) Pub. No.: US 2026/0334245 A1
(43) Pub. Date: Oct. 22, 2026

(54) CHIP PACKAGING STRUCTURE

(71) Applicants: Avary Holding (Shenzhen) Co., Limited., Shenzhen (CN); HongQiSheng Precision Electronics (QinHuangDao) Co., Ltd., Qinhuangdao (CN)

(72) Inventors: ZHI-YONG HUANG, Shenzhen (CN); YUAN-YU LIN, New Taipei (TW)

(21) Appl. No.: 19/726,719

(22) Filed: Jun. 30, 2026

Related U.S. Application Data
(62) Division of application No. 18/518,711, filed on Nov. 24, 2023.
Application No. 18/518,711 is a continuation-in-part of application No. PCT/CN2022/141604, filed on Dec. 23, 2022.

(51) Int. Cl. H10W 70/05; H10W 72/00; H10W 72/90; H10W 74/01

(52) U.S. Cl. CPC H10W 70/099; H10W 74/019; H10W 72/07236; H10W 72/07237; H10W 72/921; H10W 72/923; H10W 72/9415

(57) ABSTRACT

A chip packaging structure includes a carrier, at least one positioning post, a chip, and a plurality of solder balls. The carrier includes a substrate and a plurality of first pads disposed on a surface of the substrate. The positioning post is disposed on the surface of the substrate where the plurality of first pads disposed. The chip includes a body and a plurality of second pads disposed on a surface of the body. At least one groove is defined on the surface of the body where the plurality of second pads is disposed. Each of the at least one positioning post is partially accommodated in a corresponding one of the at least one groove. The solder balls are disposed between the plurality of first pads and the plurality of second pads. The plurality of solder balls are connected the carrier to the chip.

### FIELD

The subject matter herein generally relates to chip packaging, and more particularly, to a chip packaging structure and a method for packaging the chip.

### BACKGROUND

During a chip packaging process, the chip may be deviated from a desired position, resulting in poor welding quality or welding gaps. A short circuit may also generate, causing the chip unusable. Therefore, there is a room for improvement in the art.

### BRIEF DESCRIPTION OF THE DRAWINGS

Implementations of the present technology will now be described, by way of example only, with reference to the attached figures.

FIG. 1 shows a chip packaging process in a related art.

FIG. 2 is a cross-sectional view showing a first solder paste formed on each first pad of a carrier according to the present disclosure.

FIG. 3 is a cross-sectional view showing a dry film covering the carrier of FIG. 2.

FIG. 4 is a cross-sectional view showing blind holes defined on the dry film of FIG. 3.

FIG. 5 is a cross-sectional view showing positioning posts formed in the blind holes of FIG. 4.

FIG. 6 is a cross-sectional view showing the dry film of FIG. 5 removed.

FIG. 7 is a cross-sectional view showing a second solder paste formed on each second pad of a chip according to the present disclosure.

FIG. 8 is a cross-sectional view showing grooves defined on the chip of FIG. 7.

FIG. 9 is a cross-sectional view of a chip packaging structure formed by connecting the chip of FIG. 8 to the carrier of FIG. 6.

FIG. 10 is a flowchart of an embodiment of a method for packaging a chip according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

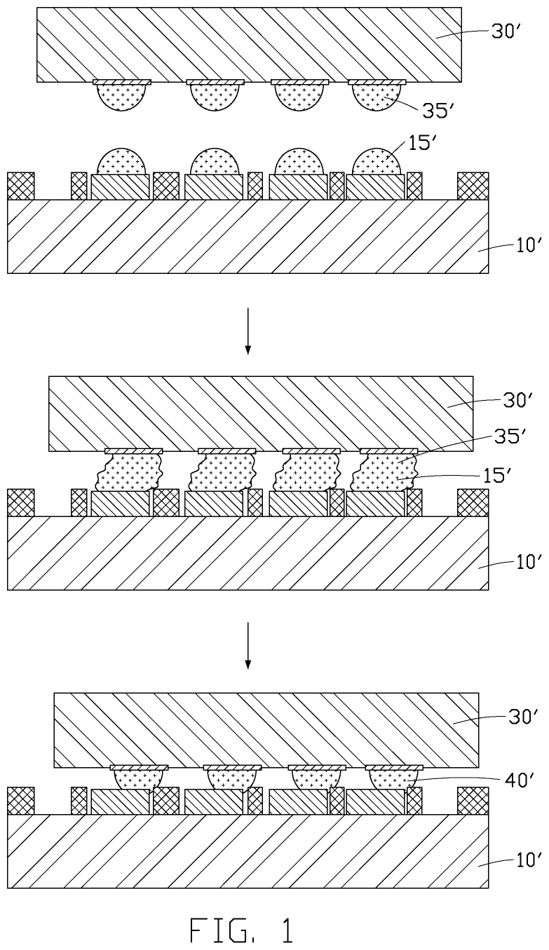

Referring to FIG. 1, a method for fixing a chip 30′ on a carrier 10′ is provided according to a related art. The method can begin at block 01.

In block 01, a plurality of first solder pastes 15′ is formed on the carrier 10′.

In block 02, a plurality of second solder pastes 35′ is formed on the chip 30′.

In block 03, the chip 30′ is placed on the carrier 10′, the second solder pastes 35′ and the first solder pastes 15′ are melted, so that the second solder pastes 35′ and the first solder pastes 15′ form solder balls 40′ to connect the chip 30′ and the carrier 10′.

When the first solder pastes 15′ and the second solder pastes 35′ are melted, a large tension occurs on the surfaces of the first solder pastes 15′ and the second solder pastes 35′. The tension causes non-directional pulling force applied on the chip 30′, causing the chip 30′ to deviate from or tilt with respect to its original position, which may lead to unexpected connections or empty soldering of the solder balls 40′, thereby forming defective products.

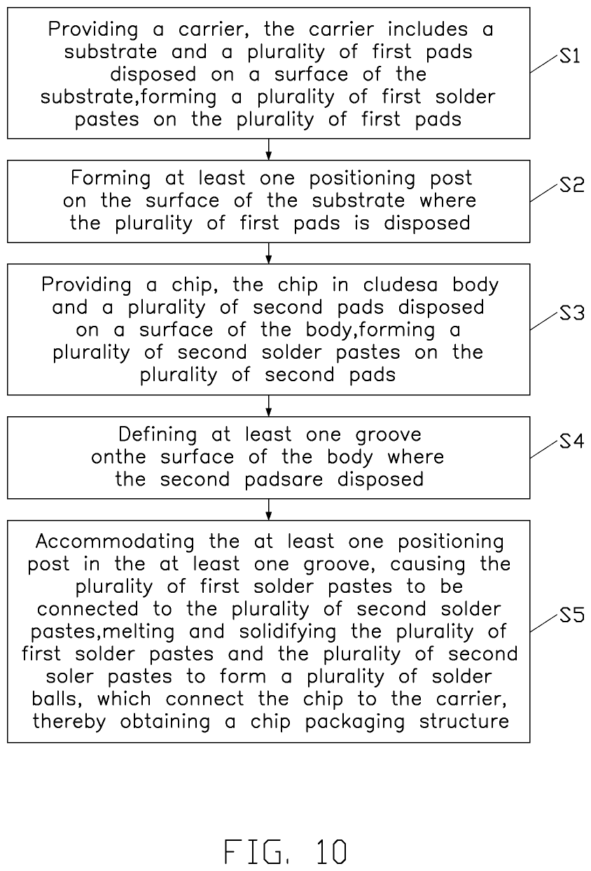

Referring to FIG. 10, a method for packaging a chip 30 is provided according to an embodiment of the present disclosure. The method can begin at block 1.

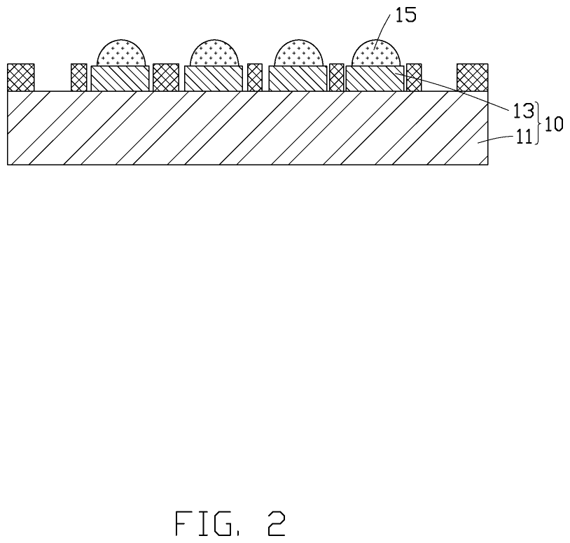

In block 1, referring to FIG. 2, a carrier 10 is provided. The carrier 10 includes a substrate 11 and a plurality of first pads 13 disposed on a surface of the substrate 11, and a first solder paste 15 is formed on each of the first pads 13.

The substrate 11 includes at least one circuit layer (not shown) and at least one dielectric layer (not shown).

The first pads 13 are electrically connected to the circuit layer. The first pads 13 can be disposed in a matrix, and two adjacent first pads 13 are spaced apart from each other. The first solder pastes 15 are disposed on an outer surface of the carrier 10. The first solder pastes 15 are disposed on surfaces of the first pads 13, and two adjacent first solder pastes 15 are spaced apart from each other.

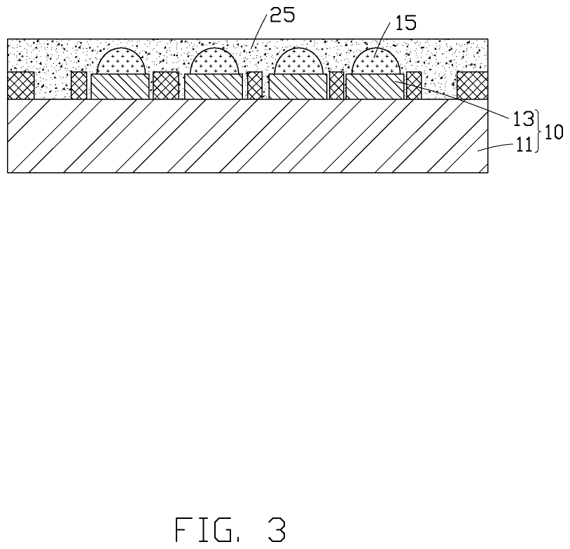

In block 2, referring to FIGS. 3 to 6, at least one positioning post 20 is formed on a surface of the substrate 11 where the first pads 13 are disposed.

Forming the positioning post 20 on the carrier 10 can be carried out by steps shown in blocks 201 to 204.

In block 201, referring to FIG. 3, a dry film 25 covers the surface of the carrier 10 where the first pads 13 are disposed, and the dry film 25 further covers the first solder pastes 15.

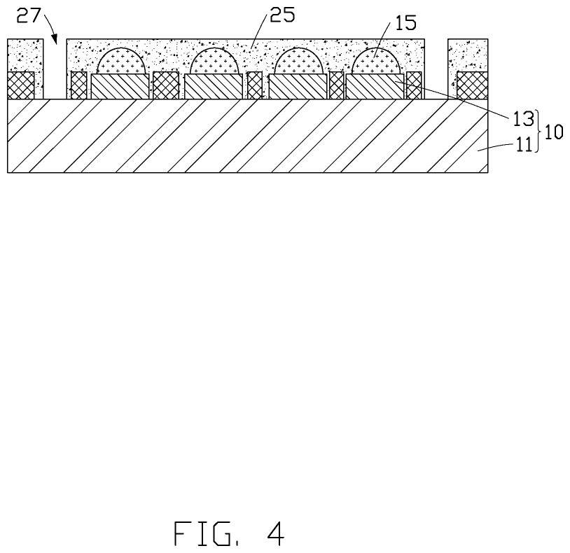

In block 202, referring to FIG. 4, the dry film 25 is subjected to an exposed and developed process to form at least one blind hole 27. Each blind hole 27 exposes partially surface of the substrate 11.

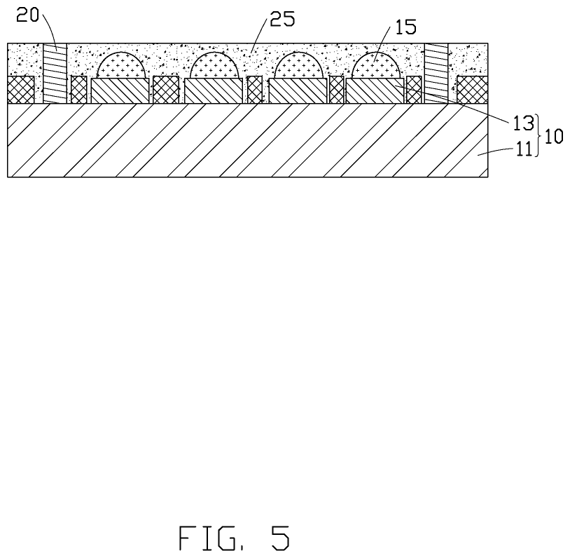

In block 203, referring to FIG. 5, the positioning post 20 is formed in the blind hole 27 to connect to the substrate 11.

The positioning post 20 can be formed in the corresponding blind hole 27 by electroplating.

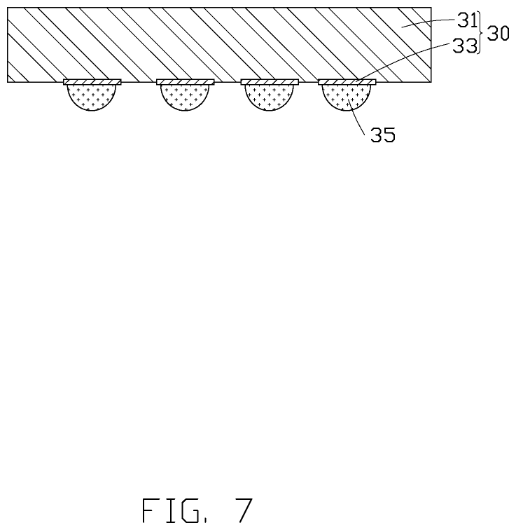

The number of blind holes 27 can be one or more. The at least one positioning post 20 is not a single cylindrical post. In some embodiments, when one blind hole 27 is formed, the blind hole 27 is a special shape, that is, the blind hole 27 is non-cylindrical. The positioning post 20 formed in the blind hole 27 is also non-cylindrical, which can prevent a chip 30 (referring to FIG. 7) from rotating and deflecting during the subsequent positioning process. In some embodiments, at least two blind holes 27 are formed. The blind holes 27 can be cylindrical or non-cylindrical, either of which can play a positioning role. In the embodiment, four blind holes 27 is formed, and the blind holes 27 are distributed at four corners of the carrier 10.

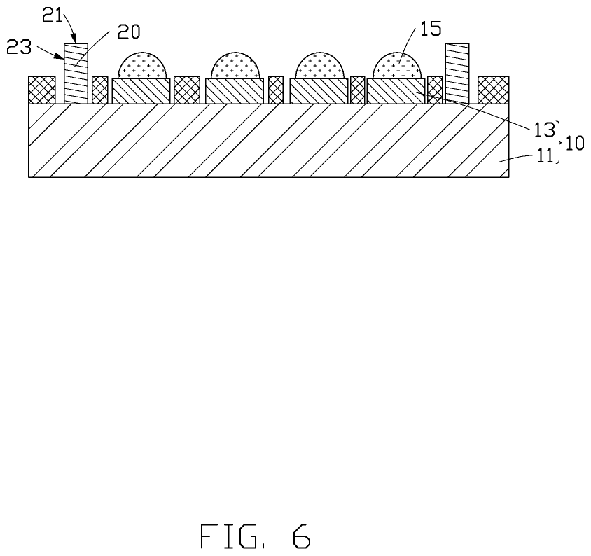

In block 204, referring to FIG. 6, the dry film 25 is removed to obtain the carrier 10 where the positioning post 20 is formed.

Each positioning post 20 includes a top surface 21 and a side surface 23. The top surface 21 is away from the substrate 11. The side surface 23 connects the top surface 21 and the substrate 11.

In block 3, referring to FIG. 7, the chip 30 is provided. The chip 30 includes a body 31 and a plurality of second pads 33 disposed on a surface of the body 31. A second solder paste 35 is formed on each of the second pads 33.

Each second pad 33 corresponds to each first pad 13. That is, the second pads 33 can be disposed in a matrix, and two adjacent second pads 33 are spaced apart from each other. The second solder pastes 35 is disposed on the second pad 33, and two adjacent second solder pastes 35 are spaced apart from each other.

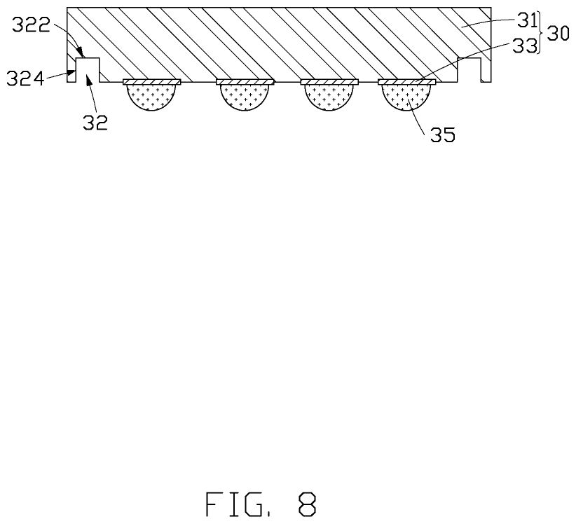

In block 4, referring to FIG. 8, at least one groove 32 is formed on the surface of the body 31 where the second pads 33 are disposed.

The groove 32 can be formed by laser. The groove 32 corresponds to the positioning post 20. The number of the groove(s) 32 is the same as the number of the positioning post(s) 20. The size of each groove 32 matches the size of the corresponding positioning post 20, so that the positioning post 20 can be accommodated in the groove 32.

In the embodiment, four grooves 32 are formed on the body 31, which are distributed at the corners of the chip 30. Each groove 32 has a bottom wall 322 and a sidewall 324. The sidewall 324 surrounds a periphery of the bottom wall 322. The bottom wall 322 is a bottom surface of the groove 32.

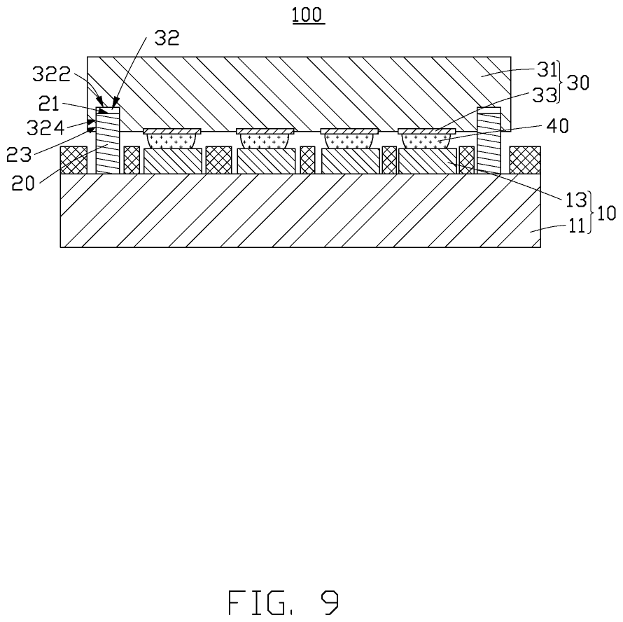

In block 5, referring to FIG. 9, each of the at least one positioning post 20 is accommodated in a corresponding one of the at least one groove 32, and each first solder paste 15 is connected to the second solder paste 35. The first solder paste 15 and the corresponding second solder paste 35 are melted and then solidified to form a solder ball 40. The solder ball 40 connect the chip 30 and the carrier 10, thereby forming a chip packaging structure 100.

One positioning post 20 is partially accommodated in the corresponding groove 32. Before the first solder pastes 15 and the second solder pastes 35 are melted, the top surface 21 of the positioning post 20 can be in contact with the bottom wall 322 of the groove 32, or can be spaced apart from the bottom wall 322 of the groove 32. At the time, both the first solder pastes 15 and the second solder pastes 35 are solid. When the first solder pastes 15 and the second solder pastes 35 are melted, the first solder pastes 15 and the second solder pastes 35 have fluidity and can be connected together. After the first solder pastes 15 and the second solder pastes 35 are solidified, each first solder paste 15 and the second solder paste 35 form one solder ball 40. Along a direction in which the chip 30 and the carrier 10 are stacked, a thickness of one solder ball 40 is less than a sum of a thicknesses of the first solder paste 15 and the corresponding second solder paste 35. After the solder balls 40 are formed, the top surface 21 of the positioning post 20 is spaced apart from the bottom wall 322 of the groove 32.

The positioning post 20 and the groove 32 can prevent the chip 30 from being deviated during the packaging process, thereby preventing a connection failure between the carrier 10 and the chip 30. In addition, the positioning post 20 can also play a heat dissipation role in the chip packaging structure 100, thereby improving the heat dissipation performance of the chip packaging structure 100.

In some embodiments, the side surface 23 of the positioning post 20 is connected to the sidewall 324 of the groove 32 to further play a limiting role. Furthermore, such connection can also increase the speed of heat transfer, and further improve the heat dissipation performance of the chip packaging structure 100.

Referring to FIG. 9, the chip packaging structure 100 according to an embodiment of the present disclosure. The chip packaging structure 100 includes the carrier 10, the positioning post 20, the chip 30, and the solder balls 40. At least one groove 32 is defined on the surface of the chip 30, the solder balls 40 are connected to the carrier 10, and one positioning post 20 is partially accommodated in the corresponding groove 32.

The carrier 10 includes the substrate 11 and first pads 13 disposed on the surface of the substrate 11. Two adjacent first pads 13 are spaced apart from each other.

The chip 30 includes the body 31 and the plurality of second pads 33 disposed on the surface of the body 31. Two adjacent second pads 33 are spaced apart from each other. Each second pad 33 is disposed corresponding to each first pad 13. That is, along the direction in which the chip 30 and the carrier 10 are stacked, a projection of each first pad 13 coincides with a projection of the corresponding second pad 33.

One solder ball 40 is disposed between each first pad 13 and the corresponding second pad 33 to achieve connection between the carrier 10 and the chip 30.

The positioning post 20 is disposed on the surface of the substrate 11 where the first pads 13 are disposed and extends toward the chip 30. The groove 32 is formed on the surface of the body 31 where the second pads 33 are disposed, and each positioning post 20 is partially accommodated in the groove 32.

Each positioning post 20 includes a top surface 21 and a side surface 23. The top surface 21 is a surface of the positioning post 20 facing away from the substrate 11. The side surface 23 connects the top surface 21 and the substrate 11. The top surface 21 is spaced apart from the bottom wall 322 of the groove 32. The side surface 23 is connected to the sidewall 324 of the groove 32, which can increase the speed of heat transfer and improve the heat dissipation performance.

In some embodiments, the positioning post 20 is made of copper.

The chip 30 is packaged by disposing positioning post 20 on the surface of the carrier 10, and the groove 32 matching the positioning post 20 is formed on the surface of the chip 30. During melting the first solder pastes 15 and the second solder pastes 35, due to the interaction between the positioning post 20 and the groove 32, the chip 30 will not be deflected due to the tension of the first solder pastes 15 and the second solder pastes 35, so that the chip packaging structure 100 meets the expected requirements.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A chip packaging structure comprising:
a carrier comprising a substrate and a plurality of first pads disposed on a surface of the substrate;
at least one positioning post disposed on the surface of the substrate where the plurality of first pads disposed;
a chip comprising a body and a plurality of second pads disposed on a surface of the body, at least one groove defined on the surface of the body where the plurality of second pads is disposed, each of the at least one positioning post partially accommodated in a corresponding one of the at least one groove; and
a plurality of solder balls disposed between the plurality of first pads and the plurality of second pads, the plurality of solder balls connecting the carrier to the chip;
wherein the at least one positioning post is not a single cylindrical post.

2. The chip packaging structure of claim 1, wherein each of the at least one positioning post comprises a top surface, the top surface faces away from the substrate, and the top surface and a bottom wall of the at least one groove are spaced apart from each other.

3. The chip packaging structure of claim 2, wherein each of the at least one positioning post comprises a side surface, the side surface connects to the substrate and connects to a sidewall of the at least one groove.

4. The chip packaging structure of claim 1, wherein each of the at least one positioning post comprises a side surface, the side surface connects to the substrate and connects to a sidewall of the at least one groove.

5. The chip packaging structure of claim 1, wherein the at least one positioning post is made of copper.

6. The chip packaging structure of claim 1, wherein the at least one positioning post comprises four positioning posts, the at least one groove comprises four grooves.

7. The chip packaging structure of claim 1, wherein the at least one positioning post comprises one positioning post, the one positioning post is non-cylindrical.

8. The chip packaging structure of claim 1, wherein the at least one positioning post comprises at least two positioning posts, each of the at least two positioning posts is cylindrical.

9. The chip packaging structure of claim 1, wherein the at least one positioning post comprises at least two positioning posts, each of the at least two positioning posts is non-cylindrical.

10. The chip packaging structure of claim 1, wherein along a direction in which the chip and the carrier are stacked, a projection of each of the plurality of first pads coincides with a projection of the corresponding of the plurality of second pads.
